(19) United States
(12) Patent Application Publication
(10) Pub. No.: US 2009/0289360 A1
(43) Pub. Date: Nov. 26, 2009

(54) WORKPIECE CONTACT PADS WITH ELEVATED RING FOR RESTRICTING HORIZONTAL MOVEMENT OF TERMINALS OF IC DURING PRESSING

(75) Inventors: YOSHIMI TAKAHASHI, BEPPU-CITY (JP); KENJI MASUMOTO, HAYAMI-GUN (JP)

Correspondence Address: TEXAS INSTRUMENTS INCORPORATED, P O BOX 655474, M/S 3999, DALLAS, TX, 75265, US

(73) Assignee: TEXAS INSTRUMENTS INC, DALLAS, TX (US)

(21) Appl. No.: 12/470,004

(22) Filed: May 21, 2009

Related U.S. Application Data
(60) Provisional application No. 61/055,674, filed on May 23, 2008.

(51) Int. Cl. H01L 23/498; H01L 21/60; H05K 1/11

(52) U.S. Cl. 257/737; 438/108; 174/261; 257/E23.068; 257/E21.506

(57) ABSTRACT

A method of forming an electronic assembly including a plurality of IC die having bonding terminals that have a solderable material thereon and a workpiece. The workpiece includes workpiece contact pads including an elevated ring having a ring height at least 5 μm above a minimum contact pad height in an indented bonding region that is within the elevated ring. The bonding terminals and/or the plurality of workpiece contact pads include solder thereon. A plurality of IC die are mounted on the workpiece. Heat is applied so that the solder becomes tacky while remaining below its melting temperature to obtain a tacked position. The plurality of IC die are pressed using a pressing tool to heat the solder to a peak temperature that is above the melting temperature. The elevated ring resists horizontal movement of the plurality of IC die from their tacked positions during pressing.

### CROSS REFERENCE TO RELATED APPLICATIONS

This application claims the benefit of Provisional Application Ser. No. 61/055,674 entitled “Substrate Structure of Semiconductor Devices”, filed May 23, 2008, which is herein incorporated by reference in its entirety.

### FIELD OF THE INVENTION

Embodiments of the present invention relate to assembly of integrated circuit (IC) comprising devices, and more particularly workpieces and to pressing-based methods for forming electronic assemblies comprising IC die joined to contact pads of workpieces with solder mediated joints.

### BACKGROUND

In recent years, as ICs have become higher in density and the degree of integration, the electrode terminals of the ICs have rapidly become higher in pin count and narrower in pitch. To mount such an IC chip on a workpiece such as a wafer, a printed circuit board (CPB), lead frame, or other semiconductor die, flip chip mounting has been widely used for reducing wiring delay. In flip chip mounting, it is typical to form solder bumps on the electrode terminals of the IC and bond the solder bumps to connecting terminals (e.g. contact pads) formed on the surface of the workpiece, via reflowing the solder bumps. Alternatively, if the IC includes TSVs, the IC can be mounted face-up to the workpiece via solder bumps or an electrically conductive finish layer on the electrically conductive (e.g. copper or tungsten) tips of the TSVs, or alternatively by providing solder on the contact pads of the workpiece.

In a first bonding method, the IC is mounted on a workpiece after a pick and place process. The solder is then reflowed by heating to a temperature above the melting point of the solder. Upon cooling, the molten solder resolidifies to form the joint. This method does not involve a pressing step.

In a second bonding method, at least one of the IC terminals and the workpiece contact pads include solder and the IC is mounted on a workpiece after a pick and place process. The solder is heated to a temperature below its melting point to obtain tackiness which enables the solder to hold the mounted IC in its aligned position (referred to sometimes as a “tacked position”) during subsequent heat plate pressing. As known in the art, tackiness refers to the ability of solder paste to hold surface mount components in place after placement but before reflow soldering. A heat plate is then used to vertically press the IC relative to the surface of the workpiece while heating the solder sufficiently to reflow the solder which upon cooling resolidifies to form a solder mediated joint. As compared to the first bonding method described above, the second bonding method generally provides higher throughput, is a simpler process, and provides lower cost interconnections.

### SUMMARY

Regarding the second bonding method described above, the Present Inventors have recognized that although the force applied by the heat plate to the IC die is generally in a vertical direction (e.g., along the z-axis; the out-of-plane direction) relative to the top surface of the workpiece (e.g., horizontally along the x-y plane; the in-plane direction), the IC die still tends to randomly shift horizontally (in-plane) relative to the workpiece surface and result in problems. The distance of the horizontal shift can result in joints that are misaligned sufficiently to result in degraded performance (e.g., that can reduce assembly yield) and/or reliability problems in the assembled electronic product. In particular, the Present Inventors have recognized that if the contact pad area and the spacing between the contact pads (pitch) are greater than the maximum horizontal IC die shift during pressing, the shift is generally harmless. However, if the bond pad dimensions and the bond pad pitch (e.g. ≦100 μm, such as ≦50 μm) are on the order of the maximum horizontal shift during pressing, the Present Inventors have recognized that misalignment caused by the horizontal shift can increase joint resistance which can result in reliability problems, and even result in electrical shorts.

Embodiments of the invention generally provide a workpiece having workpiece contact pads that include an elevated ring and an indented bonding region with the ring. The Present Inventor's addition of elevated rings perimeters and indented bonding regions has been found to help trap the IC bonding conductor (e.g., solder bumps) therein and thus reduces the random horizontal movement of the IC from its aligned tacked position following pressing for any of the possible in-plane movement directions (i.e. for all 360 degree movements). Solder is defined herein as a metal alloy that can be used to bond other metals together. In a typical embodiment, the elevated rings have a maximum height that is at least 5 μm and generally at least 10 μm above a minimum contact pad height in the indented bonding regions.

### BRIEF DESCRIPTION OF THE DRAWINGS

FIG. 1 shows steps in an exemplary method for forming an electronic assembly including at least one IC joined to a workpiece having contact pads including an elevated ring and an indented bonding region, according to an embodiment of the invention.

FIG. 2A shows a simplified cross section depiction of an electronic assembly including at least one IC joined to a workpiece having contact pads including an elevated ring and an indented bonding region, according to an embodiment of the invention.

FIG. 2B shows a simplified cross section depiction of an electronic assembly including at least one IC joined to a workpiece having contact pads including an elevated ring and an indented bonding region, according to another embodiment of the invention.

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

Spatially relative terms, such as “beneath,” “below,” “lower,” “above,” “upper” and the like may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

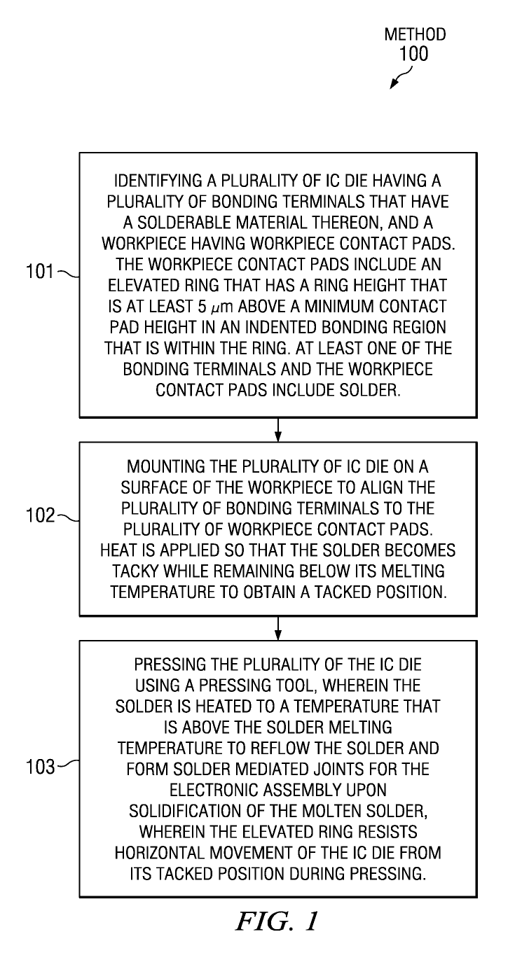

Embodiments of the invention describe workpieces having contact pads with an elevated ring that restrict horizontal movement of the IC die and its bonding terminals during assembly processing including pressing, and methods for forming an electronic assembly using such workpieces. FIG. 1 shows steps in an exemplary method 100 for forming an electronic assembly including at least one IC joined to a workpiece having contact pads including an elevated ring and an indented bonding region, according to an embodiment of the invention. Step 101 comprises identifying a plurality of IC die comprising integrated circuitry having a plurality of bonding terminals that have a solderable material thereon, and a workpiece. At least one of the top surface and the bottom surface of the IC die comprise bonding terminals which are coupled to nodes in the integrated circuitry (e.g., power, ground, I/Os). As defined herein a “solderable material” includes both solders and solder wettable materials, such as Pd and Au. At least one of the bonding terminals and the workpiece contact pads include solder thereon to allow formation of a solder mediated joint following pressing as described below.

The bonding terminals can generally comprise any suitable bonding structure such as bond pads, through substrate vias (TSVs), or pillars. For example, the plurality of bonding terminals conductors can comprise TSVs having protruding TSV tips (e.g., tips 10 to 35 μm in height), which permits the plurality of IC die to be placed and bonded face-up on the workpiece surface. In another embodiment, the bonding terminals comprise pillars or stud bumps (e.g., solder or gold bumps), which permits the IC die to be placed and bonded in a flip-chip orientation on the workpiece surface. The TSV or pillar, such as in the case of copper, can include a surface finish, such as electroless Ni/Pd or Ni/Au. As known in the art, Pd and Au are easily wettable by solder. Alternatively, The TSV or pillars can include solder thereon. Surface finishes or solder can prevent copper from be directly exposed to the environment where it tends to oxidize.

The workpiece surface comprises a plurality of workpiece contact pads (e.g., land pads). The plurality of contact pads have an elevated ring having a ring height that is at least 5 μm and generally at least 10 μm above a minimum contact pad height in an indented bonding region that is within the elevated ring. At least one of the bonding terminals and the workpiece contact pads include solder thereon. The workpiece can comprises a package substrate, such as a printed circuit board (PCB), a lead frame sheet, or a wafer.

Embodied as a PCB, the workpiece substrate can be organic (e.g., BT, FR4, etc.), ceramic, glass, tape, and/or made from other dielectric materials. Furthermore, the substrate may have one or more conductive layers, including features such as contact pads, bond fingers, traces, conductive planes, etc., for transmission of electrical signals, attachment of wire bonds, solder balls, etc., to enhance mounting of electrical components, for power/ground planes, etc. Vias or other electrically conductive regions may be used to electrically couple conductive regions through substrate.

In one embodiment the joint metallization is copper based (e.g., the IC die include copper TSVs, copper pillars, or copper bond pads) with solder mediation. As noted above, solder coatings on copper help avoid oxidation of the copper. The solder is also generally effective works to absorb (compensate for) tilt during pressing, or TSV tip or pillar height variation. In one embodiment of the invention the solder thickness is 6 to 20 μm. As described above, solder can be on the TSV tips, pillars, or on the bump pads of the IC, and/or the workpiece contact pads.

Step 102 comprises mounting the plurality of IC die on a surface of the workpiece to align the plurality of bonding terminals to the plurality of workpiece contact pads. Heat is applied so that the solder becomes tacky while remaining below its melting temperature to obtain a tacked position for the plurality of bonding terminals relative to the plurality of workpiece contact pads.

Step 103 comprises pressing the plurality of the IC die using a pressing tool, wherein the solder is heated to a temperature that is above the solder melting temperature to reflow the solder and form solder mediated joints for the electronic assembly upon solidification of the molten solder. The elevated ring resists horizontal movement of the IC die from its tacked position during pressing to improve alignment between the bonding terminals of the IC and the workpiece contact pads. Although embodiments of the invention are generally described for pressing a plurality of single IC die on a workpiece surface, those having ordinary skill in the art will recognize embodiments of the invention applying for pressing a plurality of stacked die comprising two or more stacked IC die.

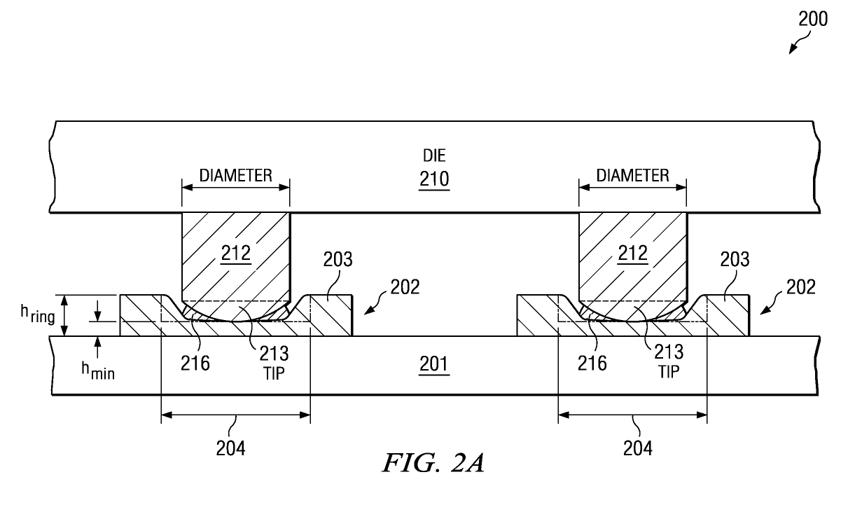

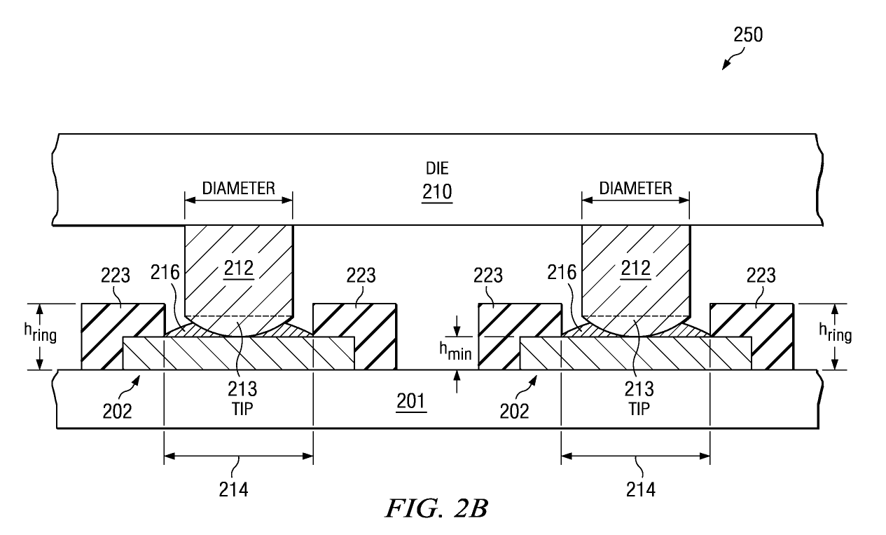

FIG. 2A shows a simplified cross section depiction of an electronic assembly 200 including at least one IC joined to a workpiece having contact pads including an elevated ring and an indented bonding region, according to an embodiment of the invention. Assembly 200 comprises a workpiece shown as substrate 201. The substrate 201 comprises a plurality of workpiece contact pads 202 thereon. The workpiece contact pads 202 have an elevated ring 203 having a ring height (shown as h_{ring}) that is at least 5 μm above a minimum contact pad height shown as hₘᵢₙ that is in an indented bonding region 204 that is within the elevated ring 203. The indented bonding region 204 can be seen to have a hollow bowl-like shape.

At least one IC die 210 has a plurality of bonding terminals 212 that include a tip region 213 having a tip area (diameter shown in FIG. 2A). The hollow bowl shaped region of indented bonding region 204 is shown providing a cross sectional area that is greater than the area of tip 213. The IC die 210 is positioned above the substrate 201 and joined to the indented bonding region 204 of the substrate 201 by a solder mediated joint 216. A distal end of the tip region 213 is positioned within the indented bonding region 204 and generally extends at least 10 μm below the top of the elevated ring 203. The elevated ring 203 of the workpiece contact pads 202 enabled improved joint alignment for electronic assembly 200 by preventing movement of the IC die 210 relative to the substrate 201 during heat pressing by a heat plate during assembly as described above.

In one embodiment the ring height is at least 10 μm above a minimum contact pad height in an indented bonding region 204, and the indented bonding region 204 provides an area of sufficient dimension so that after a distal end of the tip region 213 is within the indented bonding region 204 it extends at least 10 μm below the top of the elevated ring 203. In a particular embodiment, the tip regions 213 comprise solder bumps and the indented bonding region comprises copper 204.

FIG. 2B shows a simplified cross section depiction of an electronic assembly 250 including at least one IC joined to a workpiece having contact pads including an elevated ring and an indented bonding region, according to another embodiment of the invention. Assembly 250 comprises a workpiece shown as substrate 201. The substrate 201 comprises a plurality of workpiece contact pads 202 thereon. The workpiece contact pads 202 comprise an elevated ring 223 comprising a dielectric layer (e.g., solder mask) that is on the workpiece bond pads 202 having a ring height (shown as h_{ring}) that is at least 5 μm and is generally at least 10 μm above a minimum contact pad height above a minimum contact pad height in an indented bonding region 214 shown as hₘᵢₙ that is located within the elevated ring 223. At least one IC die 210 has a plurality of bonding terminals 212 that include a tip region 213 having a tip area (diameter shown in FIG. 2A). The IC die 210 is positioned above the substrate 201 and joined to the indented bonding region 204 of the substrate 201 by a solder mediated joint 216. A distal end of the tip region 213 is positioned within the indented bonding region 204 and extends at least 10 μm below the top of the elevated ring 223.

Workpieces have workpiece contact pads comprise elevated rings and indented bonding regions located within the elevated rings can be formed using a variety of assembly processes. One method comprises etching using an etch mask, such as a lithographically defined photoresist or a dielectric mask. Another method comprises laser ablation. Laser ablation does not generally require masking. Both of these methods provide contact pads that comprise a bond pad metal, with the elevated ring consisting of the same bond pad metal.

Other methods do not involve etching of the workpiece contact pad material. One such method comprises defining a masking material (e.g., solder mask) pattern on top of the workpiece contact pads. Another method comprises forming a mask pattern over the workpiece contact pads then depositing a metal on the workpiece contact pad material. For example, copper electroplating can be used to plate a capping metal layer on copper contact pad material with a portion extending over the masking layer adjacent to the contact or via.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. Furthermore, to the extent that the terms “including,” “includes,” “having,” “has,”, “with,” or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the following claims.

We claim:

1. A method of forming an electronic assembly, comprising:
identifying a plurality of IC die each having a plurality of bonding terminals that have a solderable material thereon and a workpiece, said workpiece comprising a plurality of workpiece contact pads, said plurality of workpiece contact pads having an elevated ring having a ring height that is at least 5 μm above a minimum contact pad height in an indented bonding region within said elevated ring, wherein at least one of said plurality of bonding terminals and said plurality of workpiece contact pads include solder thereon;
mounting said plurality of said IC die on a surface of said workpiece to align said plurality of bonding terminals to said plurality of workpiece contact pads;
applying heat so that said solder becomes tacky while remaining below its melting temperature to obtain a tacked position for said plurality of bonding terminals relative to said plurality of workpiece contact pads, and
pressing said plurality of said IC die using a pressing tool, wherein said solder is heated to a peak temperature that is above said melting temperature, wherein said elevated ring resists horizontal movement of said plurality of IC die from said tacked position during said pressing.

2. The method of claim 1, wherein said mounting comprises flip chip mounting said IC die.

3. The method of claim 2, wherein said plurality of bonding terminals comprise pillars.

4. The method of claim 1, wherein said mounting comprises mounting said IC die face up, further wherein said plurality of bonding terminals comprise through substrate vias (TSVs).

5. The method of claim 4, wherein said solderable material on said plurality of bonding terminals comprises an outer layer of Pd or Au, and said plurality of workpiece contact pads include said solder thereon.

6. The method of claim 1, wherein said plurality of bonding terminals include said solder bumps thereon and said plurality of workpiece contact pads comprise copper.

7. The method of claim 1, wherein said workpiece comprises a wafer, a printed circuit board or a lead frame sheet.

8. The method of claim 1, wherein said plurality of workpiece contact pads comprise a bond pad metal, and said elevated ring consists of said bond pad metal.

9. The method of claim 8, wherein said plurality of bonding terminals include a tip region having a tip area and said indented bonding region comprises a hollow bowl shaped region that provides a cross sectional area that is greater than said tip area.

10. The method of claim 9, wherein said plurality of bonding terminals comprise solder bumps.

11. The method of claim 9, wherein said plurality of bonding terminals comprise through substrate vias (TSVs) or pillars.

12. The method of claim 1, wherein said plurality of workpiece contact pads comprise a bond pad metal, and said elevated ring comprises a dielectric layer on said bond pad metal.

13. The method of claim 12, wherein said plurality of workpiece contact pads include a capping metal layer formed over a portion of said dielectric layer and said bond pad metal layer.

14. The method of claim 1, wherein said ring height is at least 10 μm and said plurality of bonding terminals include a tip region having a tip area, and said indented bonding region provides an area of sufficient dimension so that after said pressing a distal end of said tip region is within said indented bonding region and extends at least 10 μm below a top of said elevated ring.

15. The method of claim 14, wherein said tip regions comprise solder bumps and said indented bonding region comprises copper.

16. The method of claim 1, wherein said plurality of workpiece contact pads comprise a bond pad metal, further comprising forming said elevated ring and said indented bonding region by etching said bond pad metal using an etch mask or by laser ablation, wherein said elevated ring consists of the said bond pad metal.

17. A method of forming an electronic assembly, comprising:
identifying a plurality of IC die each having a plurality of solder bump comprising bonding terminals and a workpiece, said workpiece comprising a plurality of workpiece contact pads, said plurality of workpiece contact pads having an elevated ring having a ring height that is at least 10 μm above a minimum contact pad height in an indented bonding region within said elevated ring;
mounting said plurality said IC die on a surface of said workpiece to align said plurality of bonding terminals to said plurality of workpiece contact pads;
applying heat so that said solder becomes tacky while remaining below its melting temperature to obtain a tacked position for said plurality of solder bumps terminals relative to said plurality of workpiece contact pads, and
pressing said plurality of said IC die using a pressing tool, wherein said solder bumps are heated to a peak temperature that is above said melting temperature, and wherein said elevated ring resists horizontal movement of said plurality of IC die from said tacked position during said pressing,
wherein said plurality of bonding terminals include a tip region having a tip area, and said indented bonding region provides an area of sufficient dimension so that after said pressing a distal end of said tip region is within said indented bonding region and extends at least 10 μm below a top of said elevated ring.

18. An electronic assembly, comprising:
a workpiece, said workpiece comprising a plurality of workpiece contact pads thereon, said plurality of workpiece contact pads having an elevated ring having a ring height that is at least 10 μm above a minimum contact pad height in an indented bonding region that is within said elevated ring, and
at least one IC die having a plurality of bonding terminals that include a tip region having a tip area and are positioned above said workpiece and joined to said bonding regions of said workpiece by a solder mediated joint,
wherein a distal end of said tip region is positioned within said indented bonding region and extends at least 10 μm below a top of said elevated ring.

19. The electronic assembly of claim 19, wherein said plurality of workpiece contact pads comprise a bond pad metal, and said elevated ring consists of said bond pad metal.

20. The electronic assembly of claim 19, wherein said tip region comprises solder bumps and said indented bonding region comprises copper.

21. The electronic assembly of claim 19, wherein said plurality of workpiece contact pads comprise a bond pad metal, and said elevated ring comprises a dielectric layer on said bond pad metal.

22. A workpiece adapted for bonding at least one IC die thereto, comprising:
a substrate comprising a plurality of workpiece contact pads thereon, said plurality of workpiece contact pads having an elevated ring having a ring height that is at least 10 μm above a minimum contact pad height in an indented bonding region that is within said elevated ring.

23. The workpiece of claim 22, wherein said workpiece comprises a wafer, a printed circuit board or a lead frame sheet.

24. The workpiece of claim 22, wherein said plurality of workpiece contact pads comprise a bond pad metal, and said elevated ring consists of said bond pad metal.

25. The workpiece of claim 22, wherein said plurality of workpiece contact pads comprise a bond pad metal, and said elevated ring comprises a dielectric layer on said bond pad metal.
